(19) United States
(12) Patent Application Publication
(10) Pub. No.: US 2012/0327589 A1
(43) Pub. Date: Dec. 27, 2012

(54) COMPUTER SYSTEM WITH AIRFLOW GUIDING DUCT

(75) Inventors: HONG-ZHI SUN, Wuhan City (CN); TIAN WANG, Wuhan City (CN)

(73) Assignees: HON HAI PRECISION INDUSTRY CO., LTD., Tu-Cheng (TW); HONG FU JIN PRECISION INDUSTRY (WUHAN) CO., LTD., Wuhan City (CN)

(21) Appl. No.: 13/408,010

(22) Filed: Feb. 29, 2012

(30) Foreign Application Priority Data
Jun. 23, 2011 (CN) 201110171305.5

(51) Int. Cl. H05K 7/20

(52) U.S. Cl. 361/679.47

(57) ABSTRACT

A computer includes a computer case and an airflow guiding duct. The computer case includes a rear plate with a number of air outlets. A bracket and a first fan are received in the case. The bracket receives a number of first heat generating components and includes a mounting plate with a number of through holes. A heat sink and a second fan are received in the case, and the second fan is attached to the heat sink for absorbing heat generated by a second heat generating component. The duct defines an hole and an opening. The through holes, the first fan, the hole, and the air outlets define a first airflow passage for cooling the first heat generating components, and the second fan, the opening, the hole, and the air outlets define a second airflow passage for cooling the second heat generating component.

### BACKGROUND

1. Technical Field

The present disclosure relates to computer systems, and more particularly to a computer system with an airflow guiding duct.

2. Description of Related Art

Heat dissipating devices perform the critical function of removing heat from an electronic device. The heat dissipating device often includes one or more fans received in a bracket. Airflow from outside of the electronic device is directed inside and then back out of the electronic device by the fan, for dissipating heat generated in the electronic device. However, if the air flows in a disorderly manner in the electronic device, it will decrease heat dissipating efficiency of the electronic device.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an isometric, exploded view of an embodiment of a computer system.

FIG. 2 is an isometric view of an airflow guiding duct of FIG. 1.

FIG. 3 is an assembled view of FIG. 1.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

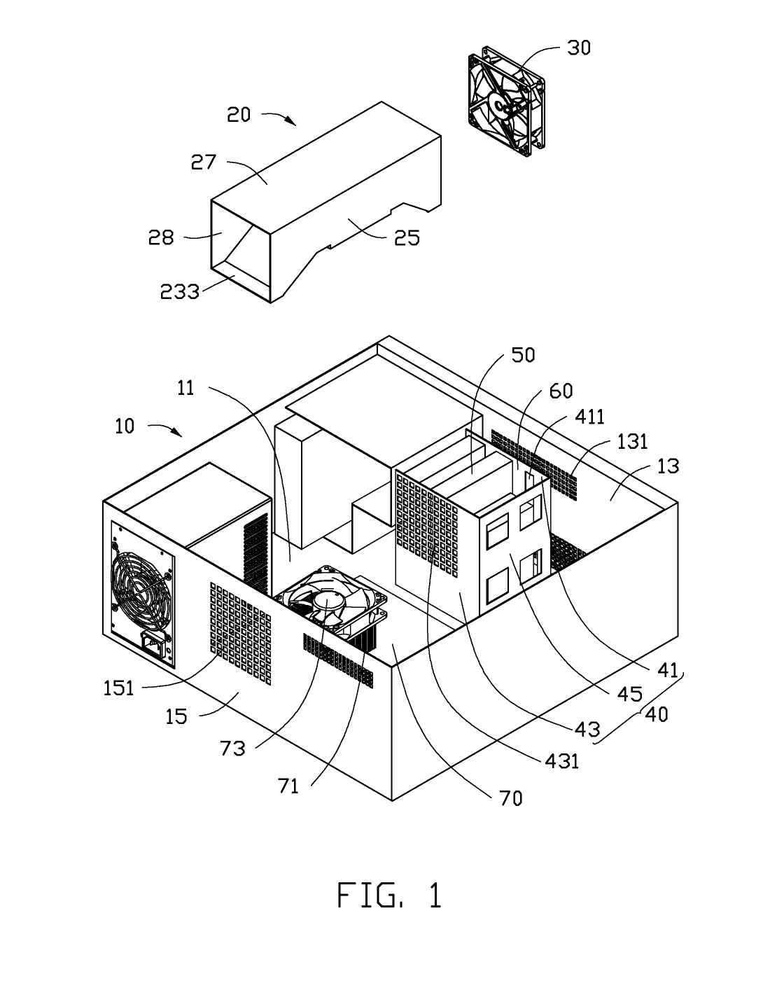

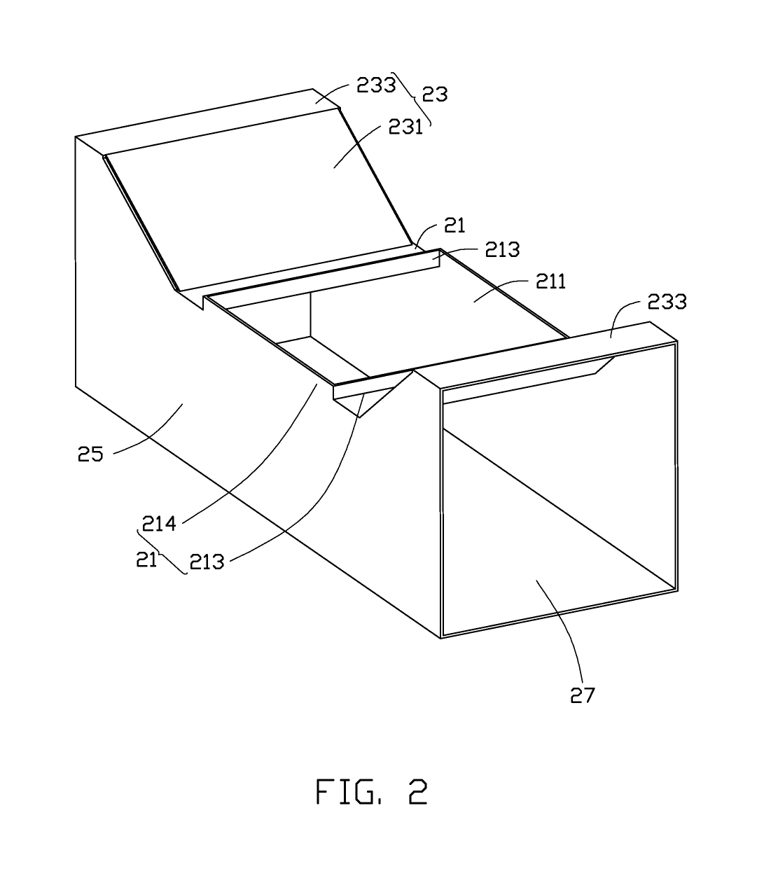

Referring to FIGS. 1 and 2, a computer system in accordance with an exemplary embodiment includes a computer case 10, an air guiding duct 20 and a first fan 30. The air guiding duct 20 and the first fan 30 received in the computer case 10.

The computer case 10 includes a bottom plate 11, a front plate 13, and a rear plate 15. The front plate 13 and the rear plate 15 are integrally formed on the bottom plate 11 or otherwise coupled with the bottom plate 11. The computer case 10 can have various configurations, such as a different wall or base configurations so long as the bottom plate 11 is adapted to couple with a cover (not shown) to create a housing. In one embodiment, the front plate 13 is substantially parallel to the rear plate 15, and substantially perpendicular to the bottom plate 11. A plurality of air intakes 131 is defined in the front plate 13, and a plurality of air outlets 151 is defined in the rear plate 15.

A bracket 40 is attached to the bottom plate 11 and adjacent to the front plate 13, and a plurality of first heat generating components 50, such as hard disk drives, is received in the bracket 40. The bracket 40 includes a first mounting plate 41, a second mounting plate 43 opposite to the first mounting plate 41, and a third mounting plate 45. The third mounting plate 45 is connected to the first and second mounting plates 41, 43. The first, second and third mounting plates 41, 43, 45 cooperatively define a receiving space 60 for receiving the first heat generating components 50. The first mounting plate 41 defines a plurality of first through holes 411, and the second mounting plate 43 defines a plurality of second through holes 431. In one embodiment, the first mounting plate 41 is substantially parallel to the second mounting plate 43 and the rear plate 15, and substantially perpendicular to the third mounting plate 45.

A motherboard 70 is located on the bottom plate 11 and includes a heat sink 71 and a second fan 73 attached to the heat sink 71. In one embodiment, the heat sink 71 and the second fan 73 are configured to absorb the heat generated by a second heat generating component (not shown), such as a CPU.

The airflow guiding duct 20 includes a bottom panel 21, two opposite guiding portions 23, two side panels 25, and a top panel 27. The bottom panel 21 defines an opening 211, and a shielding portion 212 extends from the four edges of the opening 211. The shielding portion 212 includes two opposite first shielding flanges 213 and two opposite second shielding flanges 214. In one embodiment, each first shielding flange 213 is substantially perpendicular to each second shielding flange 214 and the bottom panel 21. Each second shielding flange 214 is integral with each side panel 25. Each guiding portion 23 includes a guiding panel 231 and a connecting panel 233 connected to the guiding panel 231. The guiding panel 231 is slanted relative to the bottom panel 21, and the guiding panel 231, the two side panels 25, and the top panel 27 cooperatively define a hole 28 for airflow. In one embodiment, the two guiding portions 23 are symmetrically distributed to the two sides of the bottom panel 21, the guiding panel 231 and the bottom panel 21 define an obtuse angle, and the connecting panel 233 is substantially parallel to the top panel 27.

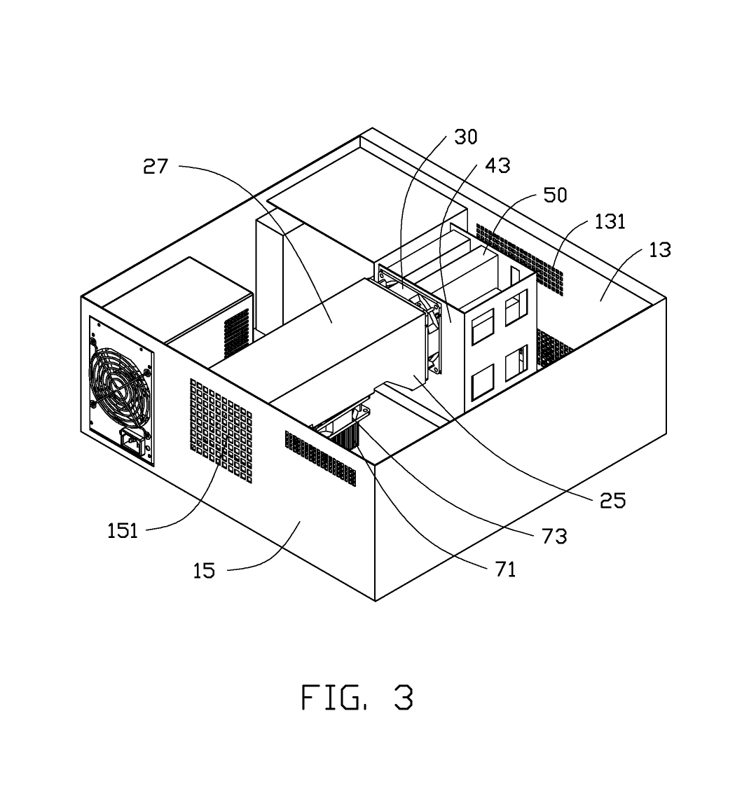

Referring to FIGS. 3-4, in assembly, the first fan 30 is secured to the second mounting plate 43 using a common fastener, so that the first fan 30 communicates with the second through hole 431. The airflow guiding duct 20 is located between the rear plate 15 and the first fan 30, and the airflow guiding duct 20 is secured to the rear plate 15 and the first fan 30 using a common fastener, so that the hole 28 communicates with the air outlets 151 and the first fan 30. The second fan 73 is thus received in the opening 211. The first shielding flanges 213 and the second shielding flanges 214 abut the outside of the second fan 73 for covering the second fan 73, so that the airflow from the second fan 73 can flow into the airflow guiding duct 20. The second through hole 431, the first fan 30, the hole 28, and the air outlets 151 cooperatively define a first airflow passage. The second fan 73, the opening 211, the hole 28, and the air outlets 151 cooperatively define a second airflow passage.

In use, the heat generated by the first heat generating components 50 transferred to airflow created by the first fan 30. The heat generated by the second generating component is transferred to the heat sink 71 and then to airflow created by the second fan 73. Air flows into the computer case 10 via the plurality of air intakes 131, flows through the bracket 40, drawn through the airflow guiding duct 20 by the first fan 30, and out of the computer case 10 via the air outlets 151. Therefore, the heat generated by the first heat generating components 50 can be removed by the first fan 30 and the airflow guiding duct 20 via the first airflow passage. In addition, air flows by the second generating component, and flows into the airflow guiding duct 20 via the opening 211, and out of computer case 10 via the plurality of air outlets 151. Therefore, the heat generated by the second generating component can be removed by the second fan 73 and the airflow guiding duct 20 via the second airflow passage.

It is to be understood, however, that even though numerous characteristics and advantages of the embodiments have been set forth in the foregoing description, together with details of the structure and function of the embodiments, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A computer system, comprising:
a computer case comprising a rear plate; and the rear plate defines a plurality of air outlets,
a bracket and a first fan received in the computer case; the bracket, receiving a plurality of first heat generating components, comprises a mounting plate that is substantially parallel to the rear plate; the mounting plate defines a plurality of through holes; and the first fan attached to the mounting plate and communicating with the plurality of through holes;
a heat sink and a second fan being located in the computer case, and the second fan is attached to the heat sink for absorbing heat generated by a second heat generating component; and
an airflow guiding duct located between the first fan and the rear plate;
a hole and an opening defined in the airflow guiding duct; and the opening is in communication with the second fan;
wherein the plurality of through holes, the first fan, the hole and the plurality of air outlets cooperatively define a first airflow passage for air flowing through; and the second fan, the opening, the hole and the plurality of air outlets cooperatively define a second airflow passage for air flowing through.

2. The computer system of claim 1, wherein the airflow guiding duct comprises a bottom panel above the second fan, and the opening is defined in the bottom panel.

3. The computer system of claim 2, wherein the bottom panel comprises a shielding portion around the opening, and the shielding portion covers the second fan.

4. The computer system of claim 3, wherein the airflow guiding duct further comprises two parallel side panels, the shielding portion comprises two opposite first shielding flanges and two opposite second shielding flanges, each first shielding flange is substantially perpendicular to the bottom panel, and each second shielding flange is integral with each side panel.

5. The computer system of claim 3, wherein the airflow guiding duct further comprises two guiding portions connected to the bottom panel, each guiding portion comprises a guiding panel and a connecting panel connected to the guiding panel, and the guiding panel is slanted relative to the bottom panel.

6. The computer system of claim 5, wherein the two guiding portions are symmetrically distributed to the opposite sides of the bottom panel.

7. The computer system of claim 5, wherein an obtuse angle is defined between the guiding panel and the bottom panel.

8. The computer system of claim 5, wherein the airflow guiding duct further comprises a top panel, and the top panel is substantially parallel to the bottom panel and the connecting panel.

9. The computer system of claim 1, wherein the plurality of first heat generating components is hard disk drives, and the second heat generating component is a CPU.

10. A computer system, comprising:
a computer case comprising a front plate and a rear plate substantially parallel to the front plate; the front plate defining a plurality of air intakes, and the rear plate defining a plurality of air outlets,
a bracket and a first fan received in the computer case, the bracket, receiving a plurality of first heat generating components, comprising a mounting plate substantially parallel to the rear plate, the mounting plate defining a plurality of through holes; and the first fan attached to the mounting plate and communicating with the plurality of through holes;
a heat sink and a second fan being received in the computer case, and the second fan attached to the heat sink for absorbing heat generated by a second heat generating component; and
an airflow guiding duct located between the first fan and the rear plate, and an hole and an opening defined in the airflow guiding duct; and the opening being in communication with the second fan;
wherein the plurality of through holes, the first fan, the hole, and the plurality of air outlets defines a first path for air cooling the plurality of first heat generating components, and the second fan, the opening, the hole, and the plurality of air outlets defines a second path for air cooling the second heat generating component.

11. The computer system of claim 10, wherein the airflow guiding duct comprises a bottom panel above the second fan, and the opening is defined in the bottom panel.

12. The computer system of claim 11, wherein the bottom panel comprises a shielding portion around the opening, and the shielding portion covers the second fan.

13. The computer system of claim 12, wherein the airflow guiding duct further comprises two parallel side panels, the shielding portion comprises two opposite first shielding flanges and two opposite second shielding flanges, each first shielding flange is substantially perpendicular to the bottom panel, and each second shielding flange is integral with each side panel.

14. The computer system of claim 12, wherein the airflow guiding duct further comprises two guiding portions connected to the bottom panel, each guiding portion comprises a guiding panel and a connecting panel connected to the guiding panel, and the guiding panel is slanted relative to the bottom panel.

15. The computer system of claim 14, wherein the two guiding portions are symmetrically distributed to the opposite sides of the bottom panel.

16. The computer system of claim 14, wherein an obtuse angle is defined between the guiding panel and the bottom panel.

17. The computer system of claim 14, wherein the airflow guiding duct further comprises a top panel, and the top panel is substantially parallel to the bottom panel and the connecting panel.

18. The computer system of claim 10, wherein the plurality of first heat generating components is hard disk drives, and the second heat generating component is a CPU.
